(19) United States
(12) Patent Application Publication
(10) Pub. No.: US 2003/0011029 A1
(43) Pub. Date: Jan. 16, 2003

(54) Method for manufacturing a mosfet having deep SD regions and SD extension regions

(75) Inventor: Tomoko Matsuda, Tokyo (JP)

Correspondence Address: McGinn & Gibb, PLLC, Suite 200, 8321 Old Courthouse Road, Vienna, VA, 22182-3817, US

(73) Assignee: NEC Corporation, Tokyo (JP)

(21) Appl. No.: 10/191,434

(22) Filed: Jul. 10, 2002

(30) Foreign Application Priority Data
Jul. 12, 2001 (JP) 2001-212073

(51) Int. Cl. H01L 29/76; H01L 29/94; H01L 31/062

(52) U.S. Cl. 257/335; 257/344; 257/338

(57) ABSTRACT

A method for forming a MOSFET includes the step of forming deep SD regions and ordinary SD regions by ion-implantation using a gate structure having a gate electrode and associated side walls as a mask, removing the side walls from the gate electrode, forming SD extension regions and pocket regions by ion-implantation using the gate electrode as a mask, and forming other side walls on the gate electrode.

### BACKGROUND OF THE INVENTION

(a) Field of the Invention The present invention relates to a method for manufacturing a MOSFET having deep SD regions and SD extension regions and, more particularly, to a method for manufacturing a MOSFET having deep SD regions and SD extension regions, which is capable of suppressing the short-channel effect thereof and operating with a lower power dissipation and at a higher speed.

(b) Description of the Related Art

Responding to requirement in higher integration, higher-speed operation and lower power dissipation of MOSFETs, a variety of proposals in the structure and fabrication methods of the MOSFETs have been presented heretofore.

FIGS. 1A to 1F consecutively show the steps of a conventional method for fabricating MOSFETs, which is described in Patent Publication JP-A-2001-15745. First, well regions, isolation regions and channel regions (not shown) are formed on a silicon substrate 11, followed by forming a gate structure including a gate oxide film 12, a gate electrode 13 and gate side walls 14 on the surface of the silicon substrate 11, as shown in FIG. 1A.

Subsequently, by using an ion-implantation technique at an injection angle of zero degrees and a rapid thermal annealing (RTA) technique, source/drain (SD) extension regions 15 are formed on the surface region of the silicon substrate 11, as shown in FIG. 1B. Thereafter, by using a selective epitaxial growth technique, elevated SD regions 16 are formed on the SD extension regions 15. The elevated SD regions 16 thus formed have oblique facets 17 thereon opposing the gate side walls 14, wherein a gap 18 are formed between the elevated SD region 16 and the gate side wall 14. The facet 17 has an angle of 54.7 degrees, for example, with respect to the substrate surface, as shown in FIG. 11.

Subsequently, pocket ion-implantation is performed through the gaps 18, wherein indium (In) ions (or p-type impurities) or antimony (Sb) ions (or n-type impurities) are obliquely injected into the silicon substrate 11 depending on the case of forming an nMOSFET or a pMOSFET. Thus, a pocket region (harrow region) 19 is formed on the side of each of SD extension regions 15, as shown in FIG. 1D. The oblique angle (α) of the injected ions is larger than the oblique angle of the facets 17. The pocket regions 19 obtained by the pocket implantation cancel protrusions of the SD extension regions 15 which underlie the gate electrode 13.

Thereafter, deposition of a silicon nitride film over the entire surface and subsequent selective etching thereof using an RIE (reactive ion etching) technique are conducted to form a gate side coat 20 covering the side of each gate side wall 14, as shown in FIG. 1E. Subsequently, ion-implantation is conducted in self-alignment with the gate structure including the gate side-coats 20, followed by a thermal treatment for activating the implanted ions, to form deep SD regions 21, which are deeper than ordinary SD regions. Thereafter, a metallic film, such as made of Ti or Co, is deposited over the entire area, followed by a thermal treatment of a portion of the metallic film on the elevated SD regions 16, whereby the metallic film is reacted with the silicon of the elevated SD regions 16 to form a metal silicide layer 29, as shown in FIG. 1F.

FIG. 2 shows the relationship between the impurity concentration (atoms/cm³) of the silicon substrate 11 and the junction capacitance (farad) in the MOSFET as described above, with an applied voltage being set at 2 volts, whereas FIG. 3 shows the relationship between the impurity concentration and the leakage current density (A/μ m²) flowing through the junction in the same case. As understood from these drawings, it is known in the art that the junction capacitance and the junction leakage current in general increase with the increase of the impurity concentration of the silicon substrate. The increase of the junction capacitance impedes a higher-speed operation of the semiconductor device, whereas the increase of the junction leakage current involves a problem of the short-channel effect, both of which degrade the transistor characteristics of the MOSFETs. Therefore, it is desired that the impurity concentration of the silicon substrate be reduced, especially in the vicinity of the SD diffused regions, for improving the transistor characteristics of the MOSFETs. The deep SD regions 21 as described above are provided in the MOSFET for this purpose.

FIG. 4 shows impurity concentration profiles employed in the manufacture of the MOSFET as described above. The graph denoted by encircled numeral “1” shows the arsenic (As) ion concentration after the pocket ion-implantation, whereas the graphs denoted by encircled numerals “2” to “5” show the boron (B) ion concentration profiles after the implantation for forming the deep SD regions, with the acceleration energy being changed between 0.5 and 4 killo-electron-volts (keV). The vertical line denoted by encircled numeral “6” shows the depth-wise location of the bottom of the SD extension regions 21.

The pocket ion-implantation is such that As ions having an opposite impurity conductivity type are injected at a specified acceleration energy, which is set for achieving a maximum concentration of As ions at the depth-wise location of the bottom of the SD extension regions 21. The As concentration profile “1” thus obtained has a moderately falling tail at the portion of the silicon substrate below the bottom of the SD extension regions 15. It is to be noted that the conductivities obtained by injecting the As and B impurities cancel each other at the location corresponding to the cross point of the As profile denoted by “1” and each of the B profiles denoted by “2” to “5”. It is to be noted that the impurity concentration caused by the pocket ion-implantation increases in the portion of the silicon substrate 11 below the each cross point. Thus, by employing a higher acceleration energy to form the deep SD regions 21 having a larger depth, a higher impurity concentration of the silicon substrate 11 due to the pocket ion-implantation can be avoided.

As described above, it is effective to form the deep SD regions 21 having a higher depth by using a higher acceleration energy in the ion-implantation, in order to lower the impurity concentration of the silicon substrate 11 and to reduce the junction capacitance as well as the junction leakage current.

However, there arises another problem in that the higher acceleration energy employed in the ion-implantation for the deep SD regions 21 increases the crystal defects in the silicon substrate due to the higher acceleration energy in the ion-implantation, in addition to deepening of the location of the deep SD regions 21 having an impurity concentration higher than 1E19 atoms/cm³.

Moreover, there arises another problem in that the impurity ions in the SD extension regions 15 are activated by the activation thermal treatment conducted after the formation of the deep SD regions 21, thereby causing diffusion and spread of the impurities toward the channel region underlying the gate electrode 13. Although a short-time activation thermal treatment may be employed in the deep SD regions 21 in view of suppressing the diffusion of the impurity ions in the SD extension regions 15, it does not provide a sufficient depth for the deep SD regions 21. In this case, another problem called “spike phenomenon” occurs wherein the current flowing from the metal silicide layer may penetrate the bottom of the deep SD regions 21. In short, there is a trade-off in the activation thermal treatment between the suppression of the expansion of the SD extension regions 15 and the achievement of a sufficient depth for the deep SD regions 21.

### SUMMARY OF THE INVENTION

In view of the above problems in the conventional technique, it is an object of the present invention to provide a method for manufacturing a MOSFET, which is capable of achieving both the suppression of the expansion of the SD extension regions and the sufficient depth for the deep SD regions, as well as achieving reduction of the junction capacitance and the junction leakage current by reducing the impurity concentration of the semiconductor substrate, whereby the resultant MOSFET can suppress the short-channel effect thereof and operate at a higher speed.

It is another object of the present invention to provide such a MOSFET.

The present invention provides a method for manufacturing a MOSFET, including the steps of: forming a first gate structure on a semiconductor substrate, the first gate structure having a gate electrode and associated first side walls; injecting impurity ions by using the first gate structure as a mask to form deep SD regions in the semiconductor substrate; injecting impurity ions by using the first gate structure as a mask to form SD regions in the semiconductor substrate, the SD regions having a depth smaller than a depth of the deep SD regions; removing the first side wall from the first gate structure; injecting impurity ions by using the gate electrode as a mask to form SD extension regions in the semiconductor substrate, the SD extensions having a depth smaller than the depth of the SD regions; and forming a second side wall on the gate electrode to obtain a second gate structure.

In accordance the MOSFET manufactured by the method of the present invention, since the ion-implantation step for forming the deep SD regions is conducted prior to the ion-implantation steps for forming the SD regions, the SD extension regions and the pocket regions, an ion-implantation to deeper location can be achieved without using a higher acceleration energy in the ion-implantation step for the deep SD region. This allows both the suppression of the expansion of the SD extension regions and the sufficient depth for the deep SD regions. In addition, a lower impurity concentration can be achieved in the semiconductor substrate in the vicinity of the MOSFET, whereby the junction capacitance and the junction leakage current can be reduced.

The present invention also provides semiconductor device including a MOSFET having a gate structure formed on a surface of a semiconductor substrate, the gate structure including a gate electrode and associated side walls each having a single insulator layer, and a pair of source and drain disposed in the semiconductor substrate and in association of the gate structure, each of the source and drain including a SD region, a SD extension region extending from the SD region parallel to the surface of the semiconductor substrate, a pocket region extending from the SD extension region parallel to the surface of the semiconductor substrate to underlie the gate structure; and a deep SD region having a depth larger than a depth of the SD region, the deep SD region being apart from the gate, structure in a direction parallel to the surface of the semiconductor substrate.

In accordance With the semiconductor device of the present invention, the gate structure having side walls each including the single insulator layer allows SD regions to be formed in self-alignment with the gate electrode with a higher dimensional accuracy.

### BRIEF DESCRIPTION OF THE DRAWINGS

FIGS. 1A to 1F are sectional views of a semiconductor device in consecutive steps of fabrication thereof.

FIG. 2 is a graph showing the relationship between the impurity concentration of a semiconductor substrate and a junction capacitance.

FIG. 3 is a graph showing the relationship between the impurity concentration of the semiconductor substrate and a junction leakage current density.

FIG. 4 is a graph showing impurity concentration profiles in a MOSFET fabricated by the method shown in FIGS. 1A to 1F.

FIGS. 5A to 5E are sectional views of a semiconductor device in consecutive steps of a method for fabricating the same according to an embodiment of the present invention.

FIG. 6 is a flowchart of the method of the embodiment.

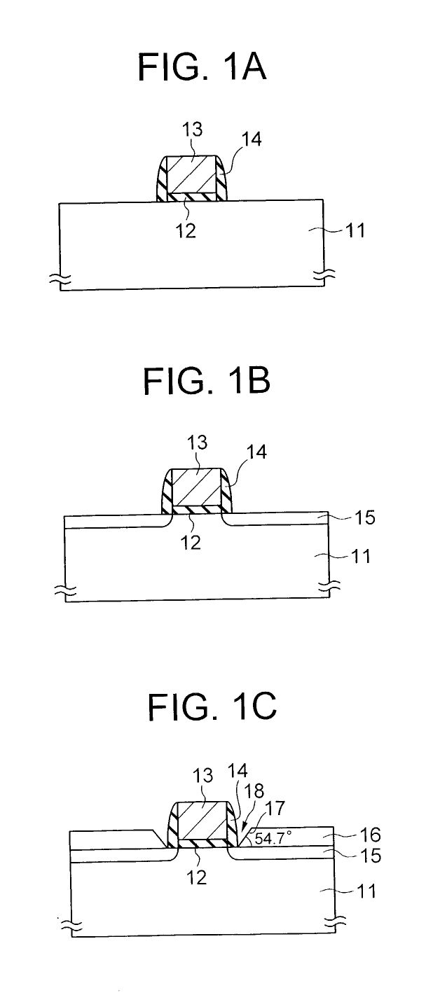

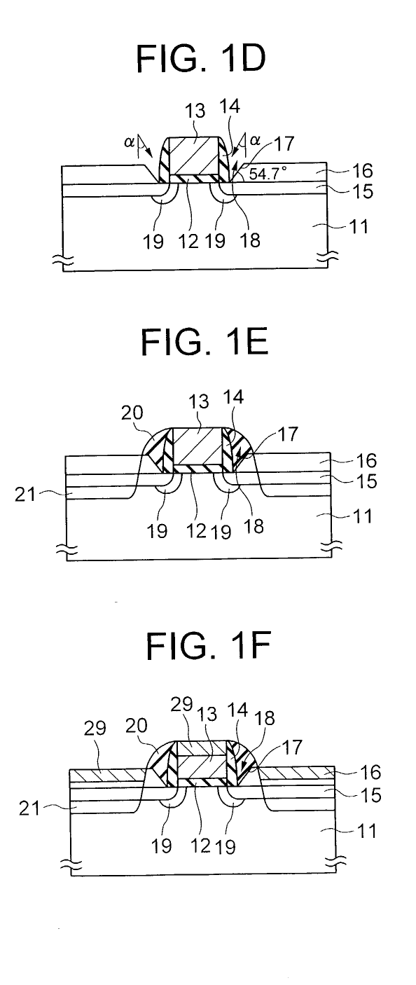

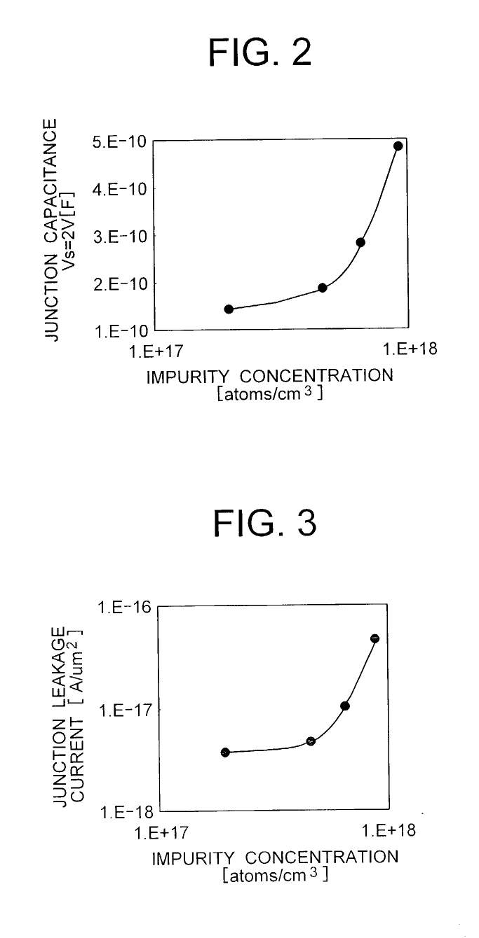

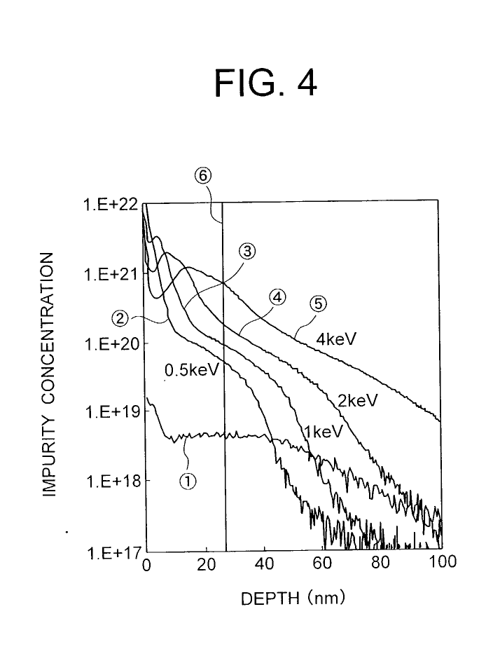

### PREFERRED EMBODIMENTS OF THE INVENTION

Now, the present invention is more specifically described with reference to accompanying drawings.

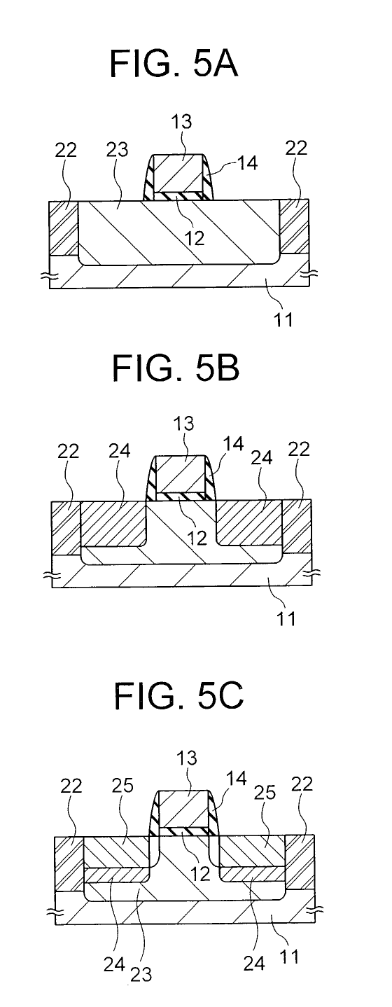

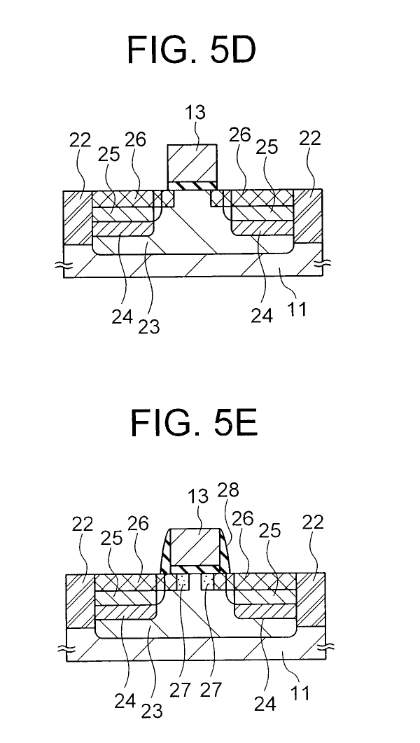

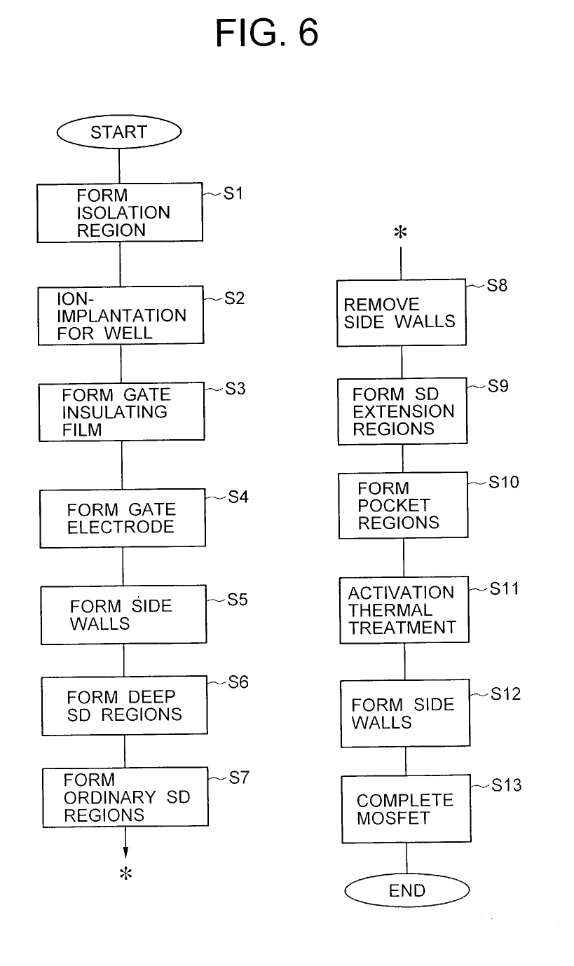

Referring to FIGS. 5A to 5E, there is shown a semiconductor device in consecutive steps of a method according to an embodiment of the present invention. FIG. 6 shows the method in a flowchart. For fabricating the semiconductor device having a MOSFET according to the method of the embodiment, an isolation trench 22 shown in FIG. 5A and receiving therein an oxide film is first formed on the surface region of a silicon substrate 11 (step S1 of FIG. 6), thereby isolating MOSFET regions from one another on the silicon substrate 11. The MOSFET regions are then ion-implanted by using p-type impurity ions and n-type impurity ions depending on the conductivity types of the MOSFETs to be formed, thereby forming p-wells (not shown) and n-wells 23 (step S2). The n-type impurities are phosphorus (P), accelerated at an acceleration energy of 100 to 150 keV, and introduced at a dosage of about 2E13 cm⁻², whereas the p-type impurities are boron (B), accelerated at an acceleration energy of 100 to 150 keV, and introduced at a dosage of about 2E13 cm⁻², for example.

A 20-angstsrom-thick gate oxide film 12 is then formed on each of the MOSFET regions by using a CVD technique and a photolithographic technique (step S3). Subsequently, a 1000- to 2000-angstrom-thick polysilicon film is deposited over the entire surface by using a CVD technique, patterned using a 0.1-μm rule fine patterning technique, to thereby form a gate electrode 13 having a gate length of about 0.1 micrometers (step S4). Thereafter, an 800-angstrom-thick silicon oxide film is deposited by a CVD technique, followed by etch-back thereof to form side-walls 14 for the gate electrode 13 (step S5). Thus, the structure shown in FIG. 5A is obtained by the above steps which are known in the art.

Subsequently, ion-implantation is conducted for forming deep SD regions 24 (step S6). In this ion-implantation step, impurity ions are introduced by using the gate structure as a mask in a self-alignment technique, with the injection angles of the ions being aligned with the (110) crystal plane of the silicon substrate 11, within a range of 0±0.5 degrees. In this text, the ion-implantation at an angle aligned with the crystal plane of the substrate is called channeling injection (or channeling implantation), and the bottom of the deep SD region 24 formed by the channeling injection is called a channeling tail.

In the channeling injection, indium (In) ions are injected to the pMOSFET region, whereas arsenic (As) or antimony (Sb) ions are injected to the nMOSFET regions. The acceleration energy for the pMOSFET regions is set at 150 keV for In ions, whereas the acceleration energy for the nMOSFET regions is set at 130 keV or 80 keV depending on the Sb or As ions used. The dosage is set at 2.5E13 cm⁻² for either ions. During the channeling injection, the pMOSFET regions are masked by a resist film while the nMOSFET regions are implanted, and vice versa. The channeling injection provides a peak concentration of the deep SD regions 24 at about 1E17 atoms/cm³, the peak concentration residing at a location which is 100 nm deep from the substrate surface.

It is desirable that the injection angle of the ions in the channeling implantation step for the deep SD regions 24 is aligned with the crystal plane of the semiconductor substrate 11. This configuration in combination with the prior ion-implantation for the deep SD regions 24 by using the channeling implantation provides an excellent. configuration for the deep SD regions 24, wherein the channeling tails have a moderate slope of the impurity concentration.

The channeling ion-implantation for the deep SD regions 24 should be conducted before an insulating film, such as an oxide film, is not formed on the portion of the substrate 11 at which the ion-implantation is to be conducted, should be a “first heavy-dosage ion-implantation”, and should be conducted in the situation wherein the semiconductor substrate is not amorphous. This suppresses expansion or protrusion of the implanted ions in the horizontal direction, and allows the implanted ions to reach deeper locations even with a moderate acceleration energy, thereby forming excellent channeling tails for the deep SD regions 24. The excellent channeling tail as formed herein has a moderate slope in the impurity concentration profile, whereby the channeling tail has a lower electric field therein and lower crystal defects. The term “first heavy-dosage ion-implantation” as used herein means a first ion-implantation conducted to the portion of the semiconductor substrate 11 except for a light-dosage ion-implantation such as an ion-implantation for forming a well region.

If there is a possibility that the semiconductor substrate 11 becomes amorphous due to the ion-implantation for forming the deep SD regions 24, the ion-implantation should be conducted at a temperature of about 100 degrees C. below zero or lower. This suppresses generation of the crystal defects in the silicon substrate, the crystal defects generally occurring together with transferring of the silicon substrate into an amorphous state.

Subsequently, ordinary ion-implantation is conducted using the gate structure as a mask, wherein B or BF₂ ions are injected into the pMOSFET regions and As or Sb ions are injected into the nMOSFET regions, to form ordinary SD regions 25 (step S7), as shown in FIG. 5C. In this step, the injection angle is set at zero degree with respect to the perpendicular of the substrate surface. The ordinary SD regions 25 extend beyond the deep SD regions 24 toward the channel region underlying the gate electrode 13, because some of the injected ions pass around beneath the side walls 14. The SD regions 25 have a smaller depth compared to the deep SD regions 24.

The injection energy is set at 2 to 3 keV for B ions or 10 to 15 keV for BF₂ ions injected in the pMOSFET regions, and set at 20 to 40 keV for As ions or 10 to 20 keV for Sb ions injected in the nMOSFET regions. In either case, the dosage is set at 1E15 to 5E15 cm⁻². The impurity concentration of the ordinary SD regions 25 thus obtained is 1E21 to 5E21 atoms/cm³ at the peak value thereof, and about 1E17 atoms/cm³ at a depth of 100 nm.

Subsequently, selective etching is conducted to remove the side walls 14 from the gate electrode 13 (step S8), followed by ion-implantation using the gate electrode 13 as a mask in a self-alignment technique to form SD extension regions 26 (step S9), as shown in FIG. 5D. The injection angle is set at zero degree. The SD extension regions 26 have a smaller depth and a larger horizontal area compared to the ordinary SD regions 25. The injection energy for forming the SD extension regions 26 is set at 0.2 to 1 keV for B ions or 2 to 5 keV for BF₂ injected in the pMOSFET regions, and 1 to 4 keV for As ions injected in the nMOSFET regions. In either case, the dosage is set at 5E14 to 1E15 atoms/cm³.

Thereafter, pocket ion-implantation is conducted, wherein n-type impurity ions are injected to the pMOSFET regions, and p-type ions are injected to the nMOSFET regions, to form pocket regions 27 around the peripheries of the SD extension regions 26 (step S10), as shown in FIG. 5E. The acceleration energy is set at 40 to 60 keV for As ions injected in the pMOSFET regions, and 10 keV for B ions injected in the nMOSFET regions. In either case, the dosage is set at 1E13 to 2E13 atoms/cm³. As ions may be replaced by Sb ions in the pMOSFET regions, whereas B ions may be replaced by In or BF₂ ions in the nMOSFET regions. Subsequently, an activation thermal treatment is conducted for activating the injected ions in the SD regions 25 and the deep SD regions 24 (step S11).

The impurity concentration of the pocket regions 27 thus obtained is 5E16 atoms/cm³ at a depth of 100 nm. The pocket regions 27 cancel the expansion of the SD extension regions 26, thereby suppressing the short-channel effect of the MOSFET. The pocket regions 27 also alleviate the concentration slope in the impurity concentration profile in the channeling tail of the deep SD regions 24. Thereafter, second side walls 28 are formed on both the sides of the gate electrode 13 (step S12), whereby the structure shown in FIG. 5E can be achieved.

Subsequently, by using steps similar to the steps of the conventional technique, a silicide layer, a plurality of interlayer dielectric films, interconnect layers, and passivation layer are formed to obtain the final structure of the semiconductor device implemented as a MOS device. It is to be noted that, although the respective regions 23 to 27 shown in FIG. 5E, for example, have more ambiguous contour lines, these regions have substantial relationships among them shown by the contour lines in view of the peak concentrations of these regions.

The moderate concentration slope of the channeling tail of the deep SD regions 24 is particularly effective to suppress the increase of the electric field at the junction caused by the higher impurity concentration in the silicon substrate and the reduction of the junction depth of the SD regions 25. This moderate impurity concentration slope was particularly observed in the channeling implantation of In and As. This solves the problem of the defects caused by the lateral diffusion of the impurity ions since it is more difficult to selectively inject the impurities in the vertical direction compared to the horizontal direction during formation of the channeling tail.

Since the above embodiments are described only for examples, the present invention is not limited to the above embodiments and various modifications or alterations can be easily made therefrom by those skilled in the art without departing from the scope of the present invention.

What is claimed is:

1. A method for manufacturing a MOSFET, comprising the steps of:
forming a first gate structure on a semiconductor substrate, said first gate structure having a gate electrode and associated first side walls;
injecting impurity ions by using said first gate structure as a mask to form deep SD regions in said semiconductor substrate;
injecting impurity ions by using said first gate structure as a mask to form SD regions in said semiconductor substrate, said SD regions having a depth smaller than a depth of said deep SD regions;
removing said first side wall from said first gate structure;
injecting impurity ions by using said gate electrode as a mask to form SD extension regions in said semiconductor substrate, said SD extension regions having a depth smaller than said depth of said SD regions; and
forming a second side wall on said gate electrode to obtain a second gate structure.

2. The method as defined in claim 1, wherein said injecting step for forming said deep SD regions uses an injection angle, which is substantially aligned to a crystal plane of said semiconductor substrate, to effect a channeling injection.

3. The method as defined in claim 2, wherein said channeling injection uses In or As ions.

4. The method as defined in claim 1, wherein said injecting step for forming said deep SD regions is performed before an oxide film is formed on a portion of a substrate surface to which said injecting step for forming said deep SD regions is to be performed.

5. The method as defined in claim 1, wherein said injecting step for forming said deep SD regions is a first heavy-dosage implantation on a portion of a substrate surface to which said injecting step for forming said deep SD regions is to be performed.

6. The method as defined in claim 1, wherein said injecting step for forming said deep SD regions is performed at a substrate temperature of 100 degrees C. below zero or lower.

7. The method as defined in claim 1, further comprising the step of injecting impurity ions by using said gate electrode as a mask to form pocket regions in vicinities of said SD extension regions.

8. A semiconductor device comprising a MOSFET including a gate structure formed on a surface of a semiconductor substrate, said gate structure including a gate electrode and associated side walls each having a single insulator layer, and a pair of source and drain disposed in said semiconductor substrate and in association of said gate structure,
each of said source and drain including a SD region, a SD extension region extending from said SD region parallel to said surface of said semiconductor substrate, a pocket region extending from said SD extension region parallel to said surface of said semiconductor substrate to underlie said gate structure; and a deep SD region having a depth larger than a depth of said SD region,
said deep SD region being apart from said gate structure in a direction parallel to said surface of said semiconductor substrate.
